(19) United States
(12) Patent Application Publication
(10) Pub. No.: US 2026/0301845 A1
(43) Pub. Date: Oct. 1, 2026

(54) READ METHOD OF MEMORY DEVICE AND MEMORY DEVICE THEREFORE

(71) Applicant: MACRONIX International Co., Ltd., Hsinchu (TW)

(72) Inventor: Hsin-Yi Lin, Hsinchu City (TW)

(73) Assignee: MACRONIX International Co., Ltd., Hsinchu (TW)

(21) Appl. No.: 19/095,051

(22) Filed: Mar. 31, 2025

(51) Int. Cl. G11C 29/52; G11C 16/34

(52) U.S. Cl. CPC G11C 29/52; G11C 16/3404; G11C 16/3427

(57) ABSTRACT

A read method of a memory device and a memory device therefore are provided. The memory device may be a 3D NAND flash memory with high capacity and high performance. The read method comprises: performing a neighboring data repairing operation while an error correction operation performed according to first data of a first page is failed. The neighboring data repairing operation comprises: performing a first read operation on a first word line to obtain a first threshold voltage state of the first page; performing a second read operation on at least one second word line to obtain at least one second threshold voltage state of at least one second page; and, correcting the first data corresponding to the first page according to the first threshold voltage state of the first page and the at least one second threshold voltage state of the at least one second page.

### BACKGROUND

### Technical Field

The disclosure relates to a data processing technology of a memory device (e.g., a 3D NAND flash memory), and in particular relates to a read method of a memory device and a memory device thereof.

### Description of Related Art

High-capacity and high-performance integrated circuit memories including 3D NAND flash memory are undergoing continuous development. The objective is to enhance data storage density by reducing memory cell dimensions through the utilization of three-dimensional stacking technology and triple-level cells (TLC).

With the advancement of semiconductor manufacturing processes, the spacing between memory cells in memory devices has become closer, thereby facilitating the occurrence of lateral charge loss effects (e.g., charge movement between word lines) and longitudinal charge loss effects (e.g., charge movement among multiple memory cells coupled to a single word line). Consequently, this phenomenon results in diminished long time data retention capability within the memory cells. That is, the long time data retention of the memory cells becomes poor. Although error correction code (ECC) may be used to reasonably recover the data stored in the memory cells, if the error rate of the data stored in the memory cells is too large, the success rate of ECC data recovery will drop significantly. Alternatively, the read voltage may be reasonably adjusted to reduce the fail bit count (FBC) in memory cell reading. However, the way of adjusting the read voltage may potentially alter previously correct data, resulting in erroneous data. Therefore, how to improve long time data retention in memory cells and reduce the read failure rate is one of the research directions.

### SUMMARY

A read method of a memory device and a memory device thereof are provided in the disclosure By reading the data of a target word line and neighboring word lines, the data in the memory cells on the target word line is corrected, thereby improving memory, thereby improving the long time data retention of memory cells and reducing the read failure rate.

A read method of a memory device is provided in an embodiment of the disclosure. The memory device includes at least one memory cell string. The at least one memory cell string includes multiple memory cells. The memory cells are divided into multiple pages. The pages correspond to multiple word lines. The read method includes the following operation. A neighboring data repairing operation is performed while an error correction operation performed according to first data of a first page is failed. The neighboring data repairing operation includes the following operation. A first read operation is performed on a first word line to obtain a first threshold voltage state of the first page, in which the first page corresponds to the first word line. A second read operation is performed on at least one second word line to obtain at least one second threshold voltage state of at least one second page, in which the at least one second page corresponds to the at least one second word line, and the at least one second page is adjacent to the first page. The first data corresponding to the first page is corrected according to the first threshold voltage state of the first page and the at least one second threshold voltage state of the at least one second page.

A memory device provided by the embodiment of the disclosure includes a memory array, a memory controller, and an error correction code (ECC) circuit. The memory array includes a memory block. The memory block includes at least one memory cell string. The at least one memory cell string includes multiple memory cells. The memory cells are divided into multiple pages. The pages correspond to multiple word lines. The memory controller controls the memory array. The ECC circuit is coupled to the memory controller to perform an error correction operation. The memory controller is configured to perform the following operation. A neighboring data repairing operation is performed while an error correction operation performed according to first data of a first page is failed. The neighboring data repairing operation includes the following operation. A first read operation is performed on a first word line to obtain a first threshold voltage state of the first page, in which the first page corresponds to the first word line. A second read operation is performed on at least one second word line to obtain at least one second threshold voltage state of at least one second page, in which the at least one second page corresponds to the at least one second word line, and the at least one second page is adjacent to the first page. The first data corresponding to the first page is corrected according to the first threshold voltage state of the first page and the at least one second threshold voltage state of the at least one second page.

Based on the above, in the read operation of a specific memory region (e.g., a specific page) of the memory device of the disclosure, if the read correction operation based on the ECC circuit fails, a neighboring data repairing operation is performed. The neighboring data repairing operation attempts to correct the data in the memory cell of the target word line by using the threshold voltage state of the neighboring word line adjacent to the target word line, thereby improving the long time data retention of memory cells and reducing the read failure rate.

### BRIEF DESCRIPTION OF THE DRAWINGS

FIG. 1 is a schematic diagram of a memory controller, an error correction code (ECC) circuit, and a memory block in a 3D NAND memory device according to an embodiment of the disclosure.

FIG. 2 is a schematic diagram illustrating multiple threshold voltage distributions in programmed operation and data retention using memory cells of a triple-level cell (TLC) type as an example according to an embodiment of the disclosure.

FIG. 3 is a waveform schematic diagram of performing a read operation to a memory cell on a word line according to an embodiment of the disclosure.

FIG. 4 is a schematic diagram of the lateral charge loss effect according to an embodiment of the disclosure.

FIG. 5 is a flowchart of a read method of a memory device according to an embodiment of the disclosure.

FIG. 6 is a detailed flowchart of step S540 in FIG. 5.

FIG. 7 is a schematic diagram conforming to steps S610 and S620 in FIG. 6 of the first embodiment of the disclosure.

FIG. 8 is a schematic diagram conforming to step S630 in FIG. 6 of the first embodiment of the disclosure.

FIG. 9 is a schematic diagram conforming to steps S610 and S620 in FIG. 6 of the second embodiment of the disclosure.

FIG. 10 is a schematic diagram conforming to step S630 in FIG. 6 of the disclosure.

### DETAILED DESCRIPTION OF DISCLOSED EMBODIMENTS

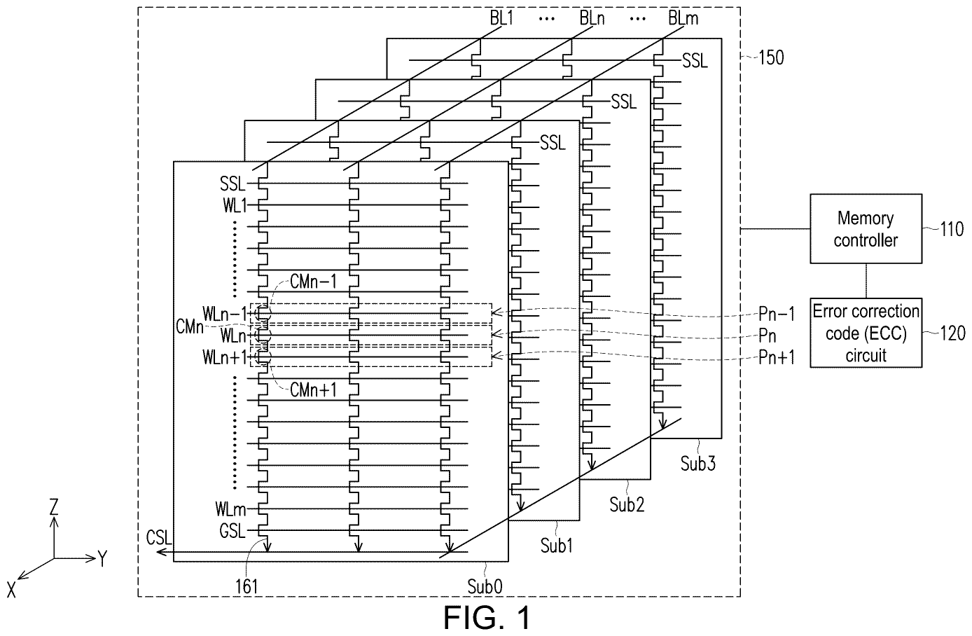

FIG. 1 is a schematic diagram of a memory controller 110, an error correction code (ECC) circuit 120, and a memory block 150 in a 3D NAND memory device according to an embodiment of the disclosure. The memory block 150 is a portion of a memory array in a memory device. The memory cells (e.g., memory cells CMn−1, CMn, CMn+1) are arranged in a three-dimensional manner in the memory block 150, such as in the XYZ coordinate system. This does not mean that the circuit of the 3D NAND memory device is limited to a three-dimensional manner. In one example, the memory block 150 may be divided into four sub-blocks (e.g., sub-blocks Sub0 to Sub3), and each sub-block may be controlled independently.

The memory cell string (e.g., memory cell string 161) includes multiple memory cells (e.g., memory cells CMn−1, CMn, CMn+1) connected in series along the Z direction. Each memory cell in the memory cell string 161 corresponds to a word line respectively. For example, memory cells CMn−1, CMn, and CMn+1 correspond to word lines WLn−1, WLn, and WLn+1 respectively. A word line (e.g., the word line WLn) may correspond to a layer in the XY plane. The transistor M may be configured as a string select transistor coupled to the string select line SSL, and another memory cell may be configured as a ground select transistor coupled to the ground select line GSL.

The string select transistor and the ground select transistor are located on opposite sides of a memory cell string (e.g., the memory cell string 161). In this example, multiple memory cell strings coupled to the same string select line SSL on the same plane (e.g., the plane defined by the Y direction and the Z direction) may be defined as one sub-block.

Each memory cell string (e.g., the memory cell string 161) is connected to a corresponding bit line (e.g., the bit line BL1) through a corresponding string select transistor (e.g., the transistor M) on the string select line SSL. Memory cell strings of the same row in different sub-blocks (e.g., sub-blocks Sub0, Sub1 . . . , etc.) along the Y direction are connected to corresponding bit lines (e.g., the bit line BL1). The string select line SSL may be a conductive line or conductive layer formed above the uppermost word line layer (e.g., the word line WL1).

Each memory cell string (e.g., the memory cell string 161) may be connected to the same common source line CSL through a corresponding ground select transistor on the ground select line GSL. The ground select line GSL may be a conductive line or conductive layer formed under the bottommost word line layer (e.g., the word line WLm). The common source line CSL may be a conductive layer formed above the substrate of the 3D memory device. Multiple string select lines SSL in the memory block 150 may be on the same conductive layer but divided into independent lines. Each independent line (string select line SSL) may independently control the operation of the corresponding sub-block (e.g., sub-block Sub0, Sub1 . . . , etc.) in the memory block 150.

In an example, multiple memory cells (including the memory cell CMn) in a sub-region (e.g., the sub-region Sub0) coupled to the same word line or word line layer (e.g., the word line WLn) may be defined as one page (e.g., the page Pn). In other words, multiple memory cells of the same word line or word line layer (e.g., the word line WLn) are divided into one page (e.g., page Pn). Pages Pn−1, Pn, and Pn+1 in this embodiment respectively include memory cells CMn−1, CMn, and CMn+1, and the pages Pn−1, Pn, and Pn+1 respectively correspond to word lines WLn−1, WLn, and WLn+1.

The memory cell in this embodiment may be a single-level type (e.g., a single-level cell (SLC) type) or a multi-level type (e.g., a multi-level cell (MLC) type, a triple-level cell (TLC) type, quad-level cell (QLC) type, etc.). The single-level cell (SLC) type stores one bit of data (e.g., logic “0” and logic “1”) through multiple threshold voltage distribution intervals. The multi-level cell type memory cells may store multi-bit data through multiple threshold voltage distribution intervals.

The same voltage is applied to the memory cell CMn on the same word line (e.g., the word line WLn). Each word line (e.g., the word line WLn) may be connected to a driving circuit, such as an X decoder (or scan driver). In one example, one or more dummy lines or layers (not shown) may be disposed between the string select line SSL and the word line layer (e.g., the word line WL1), and between the ground select line GSL and the bottommost word line layer (e.g., the word line WLm).

The memory device also includes a memory controller 110 and an ECC circuit 120 to implement corresponding operations on the memory cells. The memory controller 110 is configured to control the memory block 150 in the memory array. The ECC circuit 120 is coupled to the memory controller 110 to perform an error correction operation.

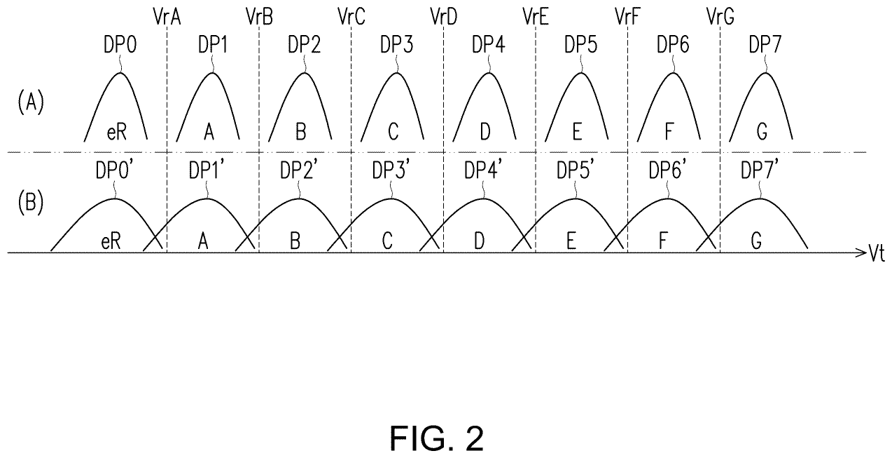

FIG. 2 is a schematic diagram illustrating multiple threshold voltage distributions in programmed operation and data retention using memory cells of a triple-level cell (TLC) type as an example according to an embodiment of the disclosure. The X-axis of FIG. 2 represents the voltage value of the threshold voltage Vt. Part (A) of FIG. 2 shows the threshold voltage distributions DPO to DP7 that the memory cells on the word line (e.g., the word line WLn) exhibits after a programming operation. The threshold voltage distributions DPO to DP7 may be divided into the erase state eR and potential states A to G according to the reference voltages VrA to VrG.

Part (B) of FIG. 2 shows the threshold voltage distributions DPO′ to DP7′ that the memory cells on the word line (e.g., the word line WLn) may exhibit after data retention. After long time data retention, the threshold voltage distribution DPO′ to DP7′ gradually becomes flat and diffuses due to the charge loss effect (e.g., lateral charge loss effect (charge movement between word lines), longitudinal charge loss effect (charge movement among multiple memory cells coupled to a single word line) . . . , etc.). If the word lines adjacent to the word line WLn are all at a low threshold voltage, but the word line WLn is at a high threshold voltage, the charge on the word line WLn will be more easily transferred to the neighboring word line, resulting in charge loss.

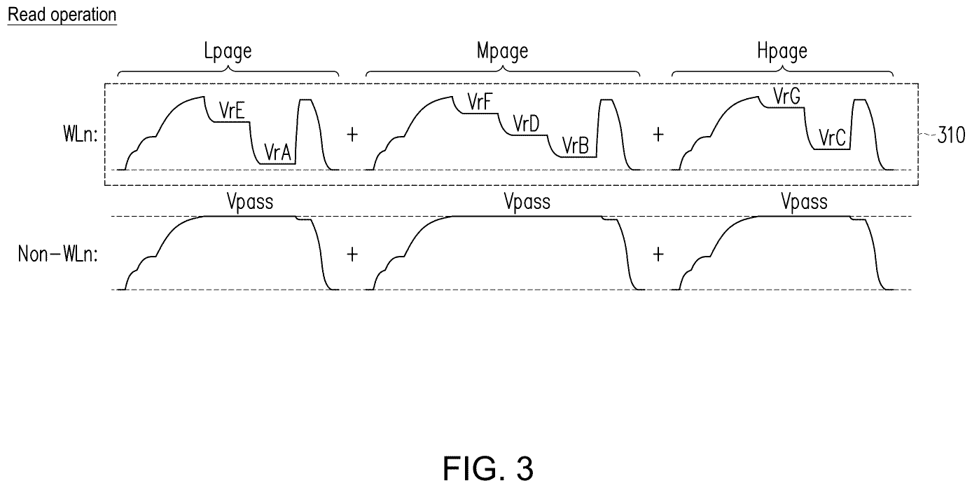

FIG. 3 is a waveform schematic diagram of performing a read operation to a memory cell on a word line WLn according to an embodiment of the disclosure. The “read operation” in this embodiment is to read in units of one page (e.g., page Pn in FIG. 1) corresponding to the word line WLn. In other words, when a read operation is performed on the memory cell on a word line WLn, a waveform 310 of a low page Lpage, a middle page Mpage, and a high page Hpage is sequentially provided to the word line WLn, and these waveforms are compared with the threshold voltage of the memory cells on word line WLn to obtain the comparison values of low page Lpage, middle page Mpage, and high page Hpage, thereby obtaining the data of all memory cells on the page Pn corresponding to the word line WLn based on these comparison values. For other word lines Non-WLn other than the word line WLn, the pass voltage Vpass is provided.

Specifically, the waveform of the low page Lpage sequentially includes the reference voltages VrE and VrA; the waveform of the middle page Mpage sequentially includes the reference voltages VrF, VrD and VrB; the waveform of the high page Hpage sequentially includes the reference voltages VrG and VrC. For the relationship between the aforementioned comparison values and the potential states, reference may be made to Table (1). Those who apply this embodiment may adjust the waveform 310 and the relationship between the comparison values in the corresponding Table (1) and each potential state (e.g., the erase state eR, potential states A to G) of the threshold voltage Vt according to their requirements.

TABLE 1

| Comparison values | | | |
|---|---|---|---|
| High page | Middle page | Low page | Potential state |
| (Hpage) | (Mpage) | (Lpage) | of TLC type |
| 1 | 1 | 1 | eR |
| 1 | 1 | 0 | A |
| 1 | 0 | 0 | B |
| 0 | 0 | 0 | C |
| 0 | 1 | 0 | D |
| 0 | 1 | 1 | E |
| 0 | 0 | 1 | F |
| 1 | 0 | 1 | G |

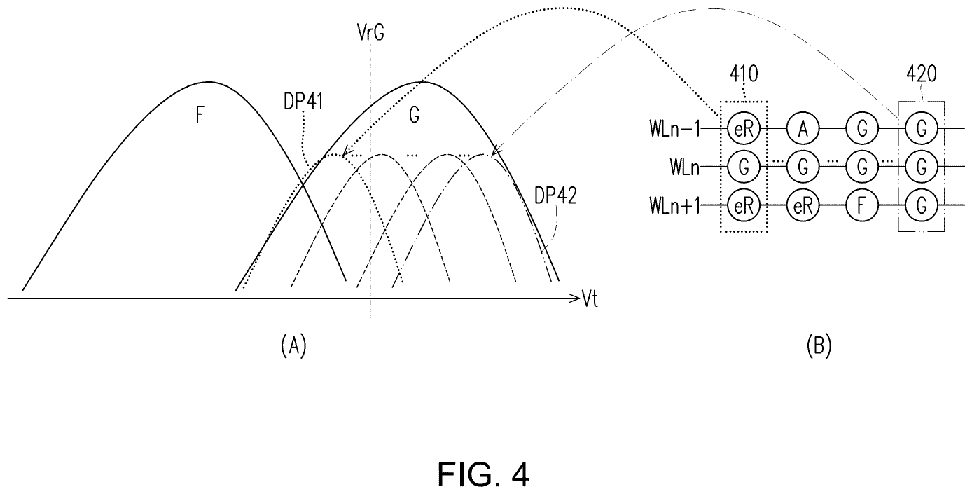

FIG. 4 is a schematic diagram of the lateral charge loss effect according to an embodiment of the disclosure. Part (A) of FIG. 4 exemplarily exhibits potential states F to G, and part (B) of FIG. 4 exhibits exemplary word lines WLn−1, WLn, WLn+1 and potential states on the corresponding memory cells. Regarding mark 410 in FIG. 4, the memory cells on the word line WLn exhibit the potential state G with a high threshold voltage, but the memory cells on the neighboring word lines WLn−1 and WLn+1 exhibit the erase state eR with a low threshold voltage. Therefore, the threshold voltage distribution DP41 of the memory cells on the word line WLn is mostly located to the left of the reference voltage VrG, so that the memory cells on the word line WLn are very likely to be read as the potential state F during the read operation. In other words, the memory cells on the word line WLn in the mark 410 are more likely to cause errors in the data stored in the memory cells due to the lateral charge loss effect.

On the other hand, regarding the mark 420 in FIG. 4, the memory cells on the word lines WLn−1, WLn, and WLn+1 all exhibit the potential state G with a high threshold voltage. Therefore, the threshold voltage distribution DP42 of the memory cells on the word line WLn is mostly located to the right of the reference voltage VrG, so the memory cells on word line WLn are very likely to be read as the correct potential state G during the read operation.

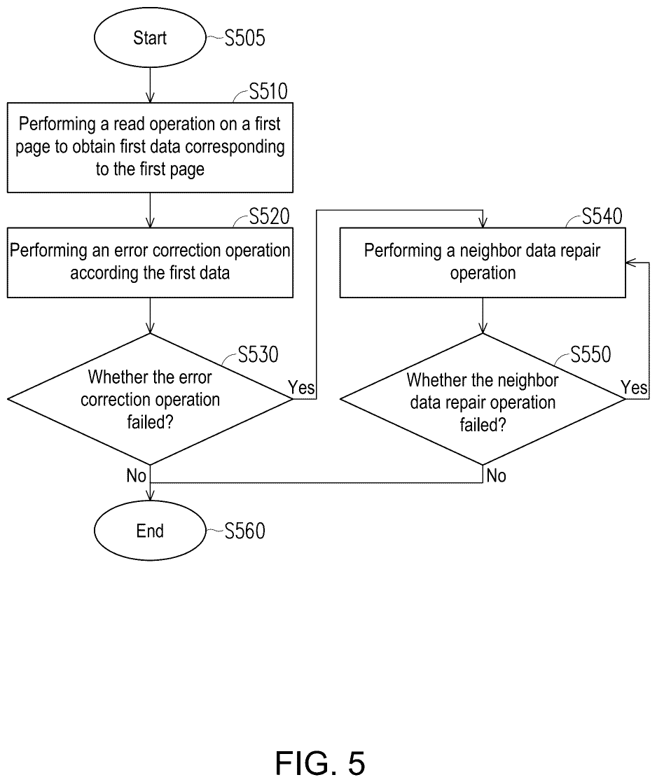

FIG. 5 is a flowchart of a read method of a memory device according to an embodiment of the disclosure. The read method of FIG. 5 may be implemented by the memory device of FIG. 1. Moreover, the read method in FIG. 5 may be applied to memory devices with different memory cell types. The types of memory cells in the memory cell block 150 in FIG. 1 may be single-level type memory cells or multi-level type memory cells. The aforementioned single-level type may be a single-level cell (SLC) type. The aforementioned multi-level type may be one of a multi-level cell (MLC) type, a triple-level cell (TLC) type, and a quad-level cell (QLC) type.

Referring to both FIG. 1 and FIG. 5, in step S505, the memory controller 110 starts to perform a read operation. In step S510, the memory controller 110 performs a read operation on the first page (e.g., the page Pn) in the memory device to obtain the first data corresponding to the page Pn. In step S520, the memory controller 110 controls the ECC circuit 120 to perform an error correction operation according to the first data of the page Pn.

In step S530, the memory controller 110 determines whether the error correction operation in step S520 fails. The error correction operation in this embodiment is to perform data correction on the first data based on the ECC technology. When the data error rate in the first data is lower than a preset value, the ECC circuit 120 may correct the errors in the first data through ECC technology to recover the correct data content of the first data. When step S530 is determined to be “no” (i.e., the error correction operation is successful), the first data has been successfully read from page Pn, so step S560 is entered to end the read operation or to perform a read operation on the next page.

However, when the data error rate in the first data is higher than the preset value, for example, when 450 or more bits of the 4 KB data are erroneous, the ECC circuit 120 is aware that there are erroneous bits in the first data, but cannot perform error correction, so that the error correction operation in step S530 fails.

In the embodiment of the disclosure, when step S530 is determined to be “yes” (i.e., the error correction operation failed), the memory controller 110 performs the neighboring data repairing operation in step S540. The neighboring data repairing operation attempts to correct the data in the memory cell of the target word line by using the threshold voltage state of the neighboring word line adjacent to the target word line, thereby improving the long time data retention of memory cells and reducing the read failure rate. In step S550, the memory controller 110 determines whether the neighboring data repairing operation fails. When step S530 is determined to be “yes” (i.e., the neighboring data repairing operation fails), step S540 may be performed repeatedly. On the other hand, when step S530 is determined to be “no” (i.e., the neighboring data repairing operation is successful), the first data has been successfully read from page Pn and the first data has been repaired through the neighboring data repairing operation. Therefore, step S560 is entered to end the read operation or to perform a read operation on the next page.

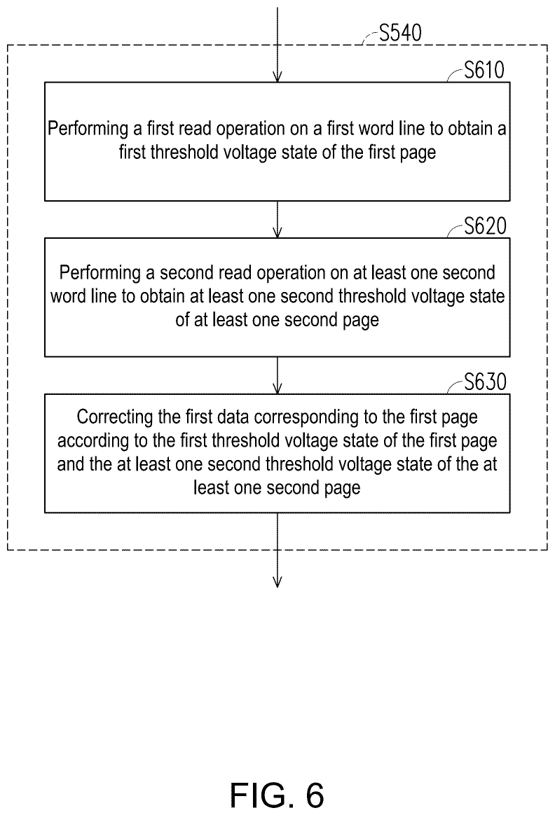

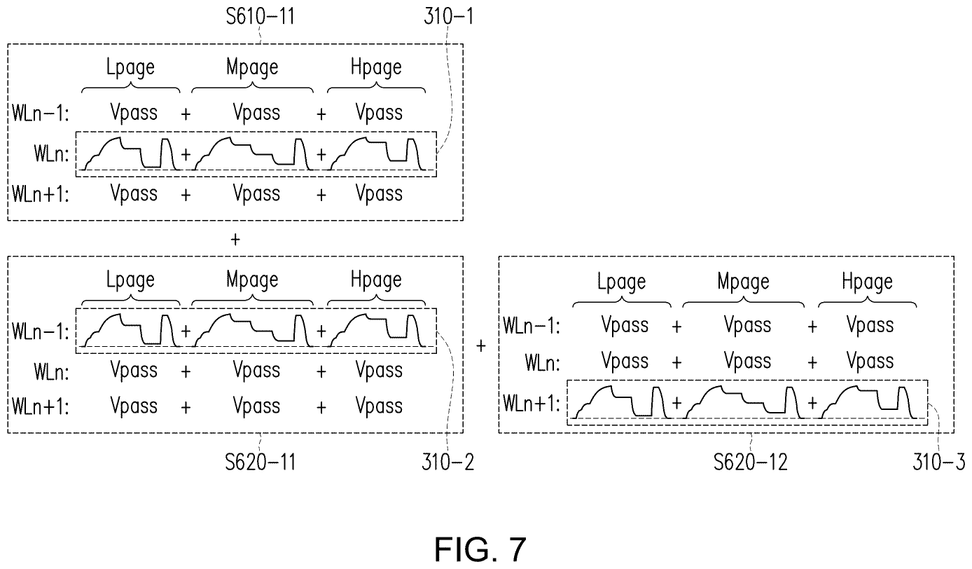

For details of the neighboring data repairing operation in step S540, reference may be made to FIG. 6. FIG. 6 is a detailed flowchart of step S540 in FIG. 5. FIG. 7 is a schematic diagram conforming to steps S610 and S620 in FIG. 6 of the first embodiment of the disclosure. Referring to FIG. 6 and FIG. 7, in step S610 of FIG. 6, the memory controller 110 performs a first read operation on a first word line (e.g., the word line WLn) corresponding to the page Pn to obtain a first threshold voltage state of the first page (page Pn). In step S610-11 of FIG. 7, the memory controller 110 provides a waveform 310-1 similar to the waveform 310 of FIG. 3 to the word line WLn to obtain the potential state of the memory cell on the word line WLn, and provide a pass voltage Vpass to neighboring word lines WLn−1 and WLn+1.

In step S620 of FIG. 6, the memory controller 110 performs a second read operation on at least one second word line (e.g., pages Pn−1 and Pn+1 corresponding to word lines WLn−1 and WLn+1 adjacent to the word line WLn) to obtain at least one second threshold voltage state of the second page (e.g., pages Pn−1 and Pn+1 corresponding to neighboring word lines WLn−1 and WLn+1). The second page (pages Pn−1 and Pn+1) respectively correspond to the second word line (e.g., word lines WLn−1 and WLn+1), and the second page (pages Pn−1 and Pn+1) are adjacent to the first page (the page Pn).

Specifically, in step S620-11 of FIG. 7, the memory controller 110 performs a second read operation on the first neighboring word line (the word line WLn−1) to obtain the first neighboring threshold voltage state of the first neighboring page (the page Pn−1). The first neighboring page (the page Pn−1) is adjacent to the first page (the page Pn) and is located at one side of the first page (the page Pn). The memory controller 110 provides a waveform 310-2 similar to the waveform 310 of FIG. 3 to the word line WLn−1 to obtain the potential state of the memory cell on the word line WLn−1. Furthermore, the pass voltage Vpass is provided to multiple word lines (word lines WLn and WLn+1) other than the first neighboring word line (the word line WLn−1).

In step S620-12 of FIG. 7, the memory controller 110 performs a second read operation on the second neighboring word line (the word line WLn+1) to obtain the second neighboring threshold voltage state of the second neighboring page (the page Pn+1). The second neighboring page (the page Pn+1) is adjacent to the first page (the page Pn) and is located at another side of the first page (the page Pn). The memory controller 110 provides a waveform 310-3 similar to the waveform 310 of FIG. 3 to the word line WLn+1 to obtain the potential state of the memory cell on the word line WLn+1. Furthermore, the pass voltage Vpass is provided to multiple word lines (word lines WLn−1 and WLn) other than the second neighboring word line (the word line WLn+1).

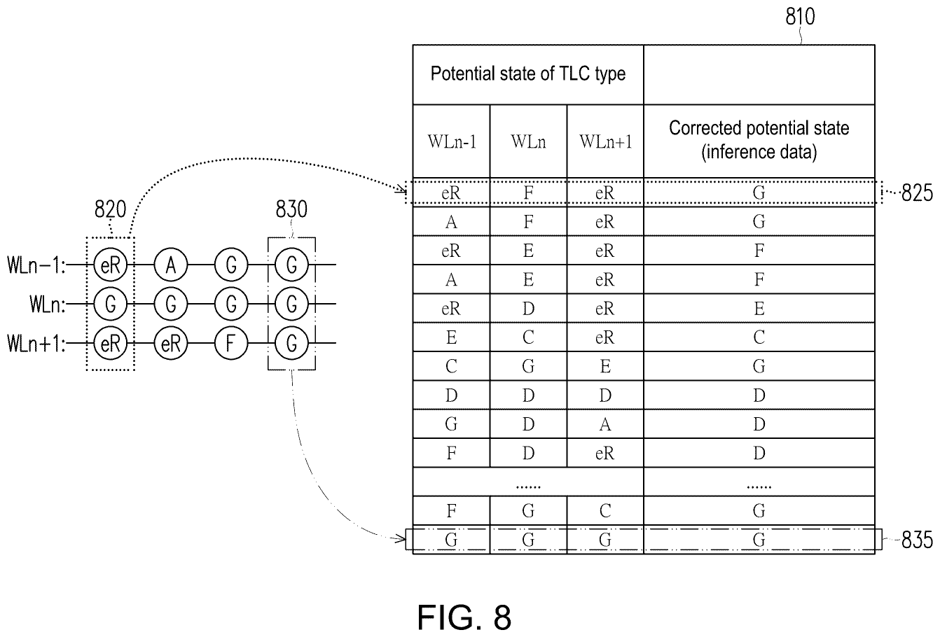

FIG. 8 is a schematic diagram conforming to step S630 in FIG. 6 of the first embodiment of the disclosure. Referring to FIG. 6 and FIG. 8 at the same time, in step S630 of FIG. 6, the memory controller 110 corrects the first data corresponding to the first page (the page Pn) according to the first threshold voltage state of the first page (the page Pn) and the second threshold voltage state of the second page (pages Pn−1 and Pn+1). For example, regarding the mark 820 in FIG. 8, assuming that the memory cells of the first page (the page Pn) on the corresponding word line WLn exhibit the potential state F of high threshold voltage, and the memory cells of pages Pn−1 and Pn+1 on the corresponding word lines WLn−1 and WLn+1 respectively exhibit the erase state eR of low threshold voltage, it may be seen that based on the aforementioned FIG. 4, the memory cells on the word line WLn are greatly affected by the charge loss effect, so the memory cells on the word line WLn may originally be in the potential state G.

The embodiment of the disclosure records or stores the situations under which the potential state may be altered due to charge loss effects in the lookup table 810. The memory controller 110 looks up the lookup table 810 according to the first threshold voltage state of the first page corresponding to the word line WLn and the second threshold voltage state of the second page corresponding to the word lines WLn−1 and WLn+1 to obtain inference data, and this inference data is used as or replaces the first data on the first page. For example, regarding mark 820 in FIG. 8, the memory controller 110 looks up a portion 825 of the lookup table 810 and learns that the potential state F of the memory cell on the first page corresponding to the word line WLn should be the potential state G. Therefore, the “potential state G” in the portion 825 of the lookup table 810 is the inference data (or referred to as the corrected potential state). Regarding mark 830 in FIG. 8, the memory controller 110 looks up a portion 835 of the lookup table 810 and learns that the potential state G of the memory cell on the first page corresponding to the word line WLn is the same as the inference data (the potential state G), and therefore no correction is required.

Through the inference data in step S630 of FIG. 6, an attempt may be made to correct the data in the memory cell of the target word line, thereby improving the long time data retention of memory cells and reducing the read failure rate. It has been confirmed through circuit verification and corresponding experiments that the first data may have a bit error rate of 7.45% when step S540 of FIG. 5 is not implemented in the read method of FIG. 5. In contrast, when the read method of FIG. 5 implements step S540 of FIG. 5, the bit error rate of the first data may be significantly reduced from 7.45% to 0.74%.

In some embodiments, those who apply this embodiment may determine whether to perform the neighboring data repairing operation of S540 on the word line located at the edge (e.g., word lines WL1 and WLm) according to their requirements. Alternatively, those who apply this embodiment may provide corresponding lookup tables for the word lines located at the edges (e.g., word lines WL1 and WLm), thereby implementing the neighboring data repairing operation of S540.

The first embodiment including FIG. 7 and FIG. 8 is an example in which the memory cell in the memory device of FIG. 1 is a multi-level type (e.g., TLC type), and the read operation of steps S610-11, S620-11, and S620-12 in FIG. 7 are all performed based on multiple reference voltages VrA to VrG. In order to save time spent in performing a read operation, in the second embodiment conforming to the disclosure, a read operation may be performed on neighboring word lines (e.g., word lines WLn−1 and WLn+1) based on a reference voltage (e.g., the reference voltage VrSLC) of a single-level type (e.g., SLC type). In other words, a read operation is performed on the pages Pn−1 and Pn+1 on neighboring word lines (e.g., word lines WLn−1 and WLn+1) by using a single-level type (e.g., SLC type) read operation and the corresponding reference voltage VrSLC, thereby reducing the time consumed in the read operation of the neighboring word lines.

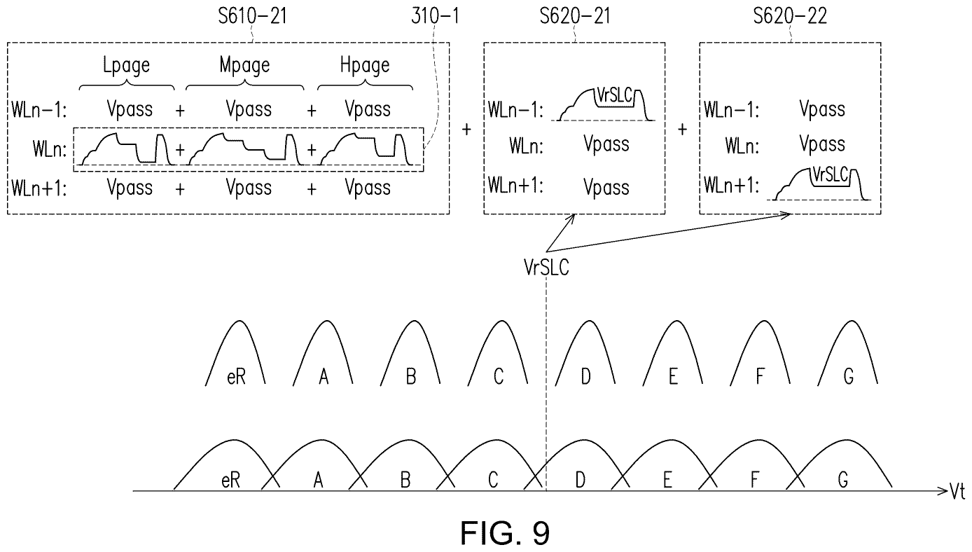

FIG. 9 is a schematic diagram conforming to steps S610 and S620 in FIG. 6 of the second embodiment of the disclosure. Step S610-21 in FIG. 9 is the same as step S610-11 in FIG. 7, but steps S620-21 and S620-22 in FIG. 9 are different from steps S620-11 and S620-12 in FIG. 7. In step S620-21 of FIG. 9, a reference voltage VrSLC of the single-level type is provided to the word line WLn−1 to determine whether the threshold voltage state of the page Pn−1 corresponding to the word line WLn−1 is logic “1” or logic “0”, and a pass voltage Vpass is provided to the word lines WLn and WLn+1. In step S620-22 of FIG. 9, the reference voltage VrSLC of the single-level type is provided to the word line WLn+1 to determine whether the threshold voltage state of the page Pn+1 corresponding to the word line WLn+1 is logic “1” or logic “0”, and a pass voltage Vpass is provided to the word lines WLn−1 and WLn. Those who apply this embodiment may correspondingly establish the lookup table required by the second embodiment according to the aforementioned establishing method of the lookup table 810 in FIG. 8, and implement step S630 in FIG. 6 according to this lookup table.

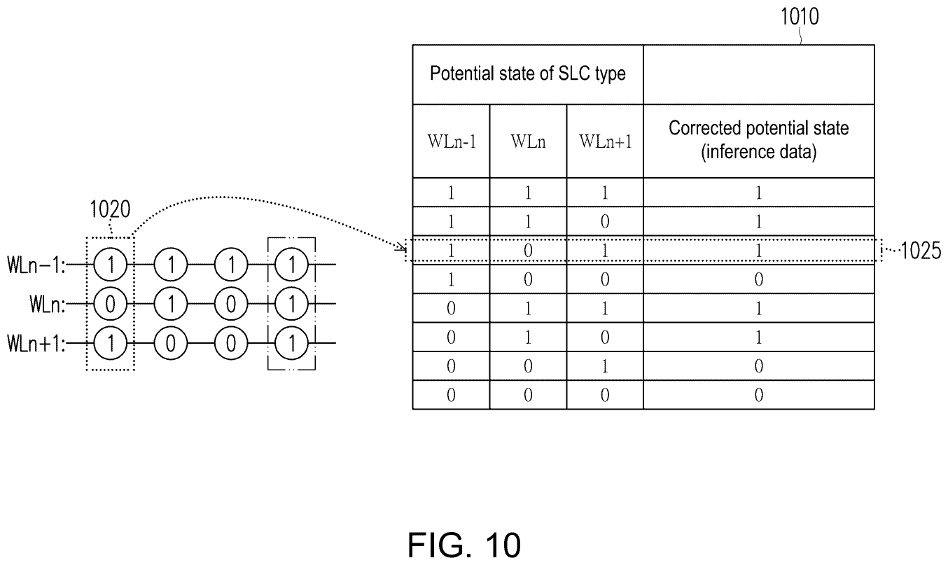

In the third embodiment, the memory cells in the memory device of FIG. 1 are implemented from a single-level type (e.g., SLC type). FIG. 10 is a schematic diagram conforming to step S630 in FIG. 6 of the disclosure. The third embodiment of the disclosure records or stores the situations under which the potential state may be altered due to charge loss effects in the lookup table 1010. The memory controller 110 looks up the lookup table 1010 according to the first threshold voltage state of the first page corresponding to the word line WLn and the second threshold voltage state of the second page corresponding to the word lines WLn−1 and WLn+1 to obtain inference data, and this inference data is used as or replaces the first data on the first page. For example, regarding mark 1020 in FIG. 10, the memory controller 110 looks up a portion 1025 of the lookup table 1010 and learns that the logic “0” of the memory cell on the first page corresponding to word line WLn should be logic “1”. Therefore, the “logic ‘1’” in the portion 1025 of the lookup table 1010 is the inference data (or referred to as the corrected potential state).

To sum up, in the read operation of a specific memory region (e.g., a specific page) of the memory device of the disclosure, if the read correction operation based on the ECC circuit fails, a neighboring data repairing operation is performed. The neighboring data repairing operation attempts to correct the data in the memory cell of the target word line by using the threshold voltage state of the neighboring word line adjacent to the target word line, thereby improving the long time data retention of memory cells and reducing the read failure rate.

What is claimed is:

1. A read method of a memory device, wherein the memory device comprises at least one memory cell string, wherein the at least one memory cell string comprises a plurality of memory cells, the plurality of memory cells are divided into a plurality of pages, the plurality of pages correspond to a plurality of word lines,
the read method comprising:
performing a neighboring data repairing operation while an error correction operation according to first data of a first page is failed,
wherein the neighboring data repairing operation comprises:
performing a first read operation on a first word line to obtain a first threshold voltage state of the first page, wherein the first page corresponds to the first word line;
performing a second read operation on at least one second word line to obtain at least one second threshold voltage state of at least one second page, wherein the at least one second page corresponds to at the least one second word line, and the at least one second page is adjacent to the first page; and
correcting the first data corresponding to the first page according to the first threshold voltage state of the first page and the at least one second threshold voltage state of the at least one second page.

2. The read method according to claim 1, wherein the read method further comprises:
performing a read operation on the first page to obtain the first data corresponding to the first page;
performing the error correction operation performed according to the first data; and
performing the neighboring data repairing operation when the error correction operation performed according to the first data is failed.

3. The read method according to claim 1, wherein correcting the first data corresponding to the first page according to the first threshold voltage state of the first page and the at least one second threshold voltage state of the at least one second page comprises:
looking up a lookup table according to the first threshold voltage state of the first page and the at least one second threshold voltage state of the at least one second page to obtain inference data; and
using the inference data as the first data corresponding to the first page.

4. The read method according to claim 1, wherein performing the second read operation on the at least one second word line to obtain the at least one second threshold voltage state of the at least one second page comprises:
performing the second read operation on a first neighboring word line to obtain a first neighboring threshold voltage state of a first neighboring page, wherein the first neighboring page is adjacent to the first page and is located on one side of the first page, and, providing a pass voltage to the plurality of word lines other than the first neighboring word line;
performing the second read operation on a second neighboring word line to obtain a second neighboring threshold voltage state of a second neighboring page, wherein the second neighboring page is adjacent to the first page and is located on another side of the first page, and, providing the pass voltage to the plurality of word lines other than the second neighboring word line.

5. The read method according to claim 1, wherein the plurality of memory cells are composed of a multi-level type.

6. The read method according to claim 5, wherein the first read operation is performed based on a plurality of reference voltages, the plurality of reference voltages correspond to the multi-level type of the plurality of memory cells, and,
the second read operation is performed based on the plurality of reference voltages, the plurality of reference voltages correspond to the multi-level type of the plurality of memory cells.

7. The read method according to claim 5, wherein the first read operation is performed based on a plurality of reference voltages, the plurality of reference voltages correspond to the multi-level type of the plurality of memory cells, and,
the second read operation is performed based on a single reference voltage, the single reference voltage corresponds to the a single-level type of the plurality of memory cells.

8. The read method according to claim 1, wherein the plurality of memory cells are composed of a single-level type.

9. A memory device, comprising:
a memory array, comprising a memory block, wherein the memory block comprises at least one memory cell string, wherein the at least one memory cell string comprises a plurality of memory cells, the plurality of memory cells are divided into a plurality of pages, the plurality of pages correspond to a plurality of word lines;
a memory controller, controlling the memory array; and
an error correction code (ECC) circuit, coupled to the memory controller to perform an error correction operation,
wherein the memory controller is configured to perform:
performing a neighboring data repairing operation while an error correction operation performed according to first data of a first page is failed,
wherein the neighboring data repairing operation comprises:
performing a first read operation on a first word line to obtain a first threshold voltage state of the first page, wherein the first page corresponds to the first word line;
performing a second read operation on at least one second word line to obtain at least one second threshold voltage state of at least one second page, wherein the at least one second page corresponds to at the least one second word line, and the at least one second page is adjacent to the first page; and
correcting the first data corresponding to the first page according to the first threshold voltage state of the first page and the at least one second threshold voltage state of the at least one second page.

10. The memory device according to claim 9, wherein the memory controller is further configured to perform:
performing a read operation on the first page to obtain the first data corresponding to the first page;
performing the error correction operation performed according to the first data; and
performing the neighboring data repairing operation when the error correction operation performed according to the first data is failed.

11. The memory device according to claim 9, wherein the memory controller looks up a lookup table according to the first threshold voltage state of the first page and the at least one second threshold voltage state of the at least one second page to obtain inference data, and
the memory controller uses the inference data as the first data corresponding to the first page.

12. The memory device according to claim 9, wherein
the memory controller performs the second read operation on a first neighboring word line to obtain a first neighboring threshold voltage state of a first neighboring page, wherein the first neighboring page is adjacent to the first page and is located on one side of the first page, and, provides a pass voltage to the plurality of word lines other than the first neighboring word line;
the memory controller performs the second read operation on a second neighboring word line to obtain a second neighboring threshold voltage state of a second neighboring page, wherein the second neighboring page is adjacent to the first page and is located on another side of the first page, and, provides the pass voltage to the plurality of word lines other than the second neighboring word line.

13. The memory device according to claim 9, wherein the plurality of memory cells are composed of a multi-level type.

14. The memory device according to claim 13, wherein the first read operation is performed based on a plurality of reference voltages, the plurality of reference voltages correspond to the multi-level type of the plurality of memory cells, and,
the second read operation is performed based on the plurality of reference voltages, the plurality of reference voltages correspond to the multi-level type of the plurality of memory cells.

15. The memory device according to claim 13, wherein the first read operation is performed based on a plurality of reference voltages, the plurality of reference voltages correspond to the multi-level type of the plurality of memory cells, and,
the second read operation is performed based on a single reference voltage, the single reference voltage corresponds to the a single-level type of the plurality of memory cells.

16. The memory device according to claim 9, wherein the plurality of memory cells are composed of a single-level type.
